(19) United States
(12) Patent Application Publication
(10) Pub. No.: US 2024/0174574 A1
(43) Pub. Date: May 30, 2024

(54) THERMAL BARRIER MATERIAL EXHIBITING MANUFACTURABILITY, HIGH TOUGHNESS AND LOW THERMAL CONDUCTIVITY

(71) Applicants: Molly Maureen O’Connor, Indianapolis, IN (US); Andreis Peter Castronova, Indianapolis, IN (US); Richard Eugene Cook, Indianapolis, IN (US); Andrew James Heidloff, Indianapolis, IN (US); William John Jarosinski, Indianapolis, IN (US)

(72) Inventors: Molly Maureen O’Connor, Indianapolis, IN (US); Andreis Peter Castronova, Indianapolis, IN (US); Richard Eugene Cook, Indianapolis, IN (US); Andrew James Heidloff, Indianapolis, IN (US); William John Jarosinski, Indianapolis, IN (US)

(21) Appl. No.: 18/516,145

(22) Filed: Nov. 21, 2023

Related U.S. Application Data
(60) Provisional application No. 63/428,507, filed on Nov. 29, 2022.

(51) Int. Cl. C04B 35/48; C04B 35/622; C23C 4/11; C23C 14/08; C23C 14/30

(52) U.S. Cl. CPC C04B 35/48; C04B 35/62222; C23C 4/11; C23C 14/083; C23C 14/30; C04B 2235/3225; C04B 2235/3229; C04B 2235/3244; C04B 2235/3251; C04B 2235/765; C04B 2235/9607; C04B 2235/9669; C23C 4/134

(57) ABSTRACT

A modified ternary Zr—Ta—Y oxide system is provided having a larger non-transformable, tetragonal phase that enables thermal barrier materials with improved properties of low thermal conductivity, higher sinter resistance, higher phase stability, and higher toughness to be created.

### RELATED APPLICATIONS

This application claims the benefit of priority to U.S. Provisional Application Ser. No. 63/428,507, filed Nov. 29, 2022, the disclosure of which is hereby incorporated by reference herein its entirety.

### FIELD OF THE INVENTION

The present invention relates to improved thermal barrier materials, and more particularly relates to thermal barrier coatings exhibiting a non-transformable, solid solution tetragonal phase that is stable over a larger compositional range relative to previous thermal barrier materials.

### BACKGROUND

The fuel efficiency of power generation and aerospace turbines increases as the operating temperatures increase. As the drive to increase turbine efficiency moves forward, this results in turbine components being exposed to increasingly higher temperatures, pushing the limits of mechanical strength, corrosion, and erosion resistance of the turbine component materials. One method used to mitigate the effects of increasing temperatures in turbines is the application of thermal barrier coatings (TBC) to the hottest engine components to provide thermal insulation to the underlying metallic or ceramic structural components. A typical TBC material known in the prior art is 6-8 weight % yttria stabilized zirconia, known as 7YSZ. 7YSZ has been the primary material used for TBCs due to its high coefficient of thermal expansion (CTE) that increases strain compliance; relatively low thermal conductivity that decreases heat transfer rates to the cooled structural components; and high toughness that provides erosion and foreign object damage (FOD) protection. While most ZrO2-based ceramic materials have relatively high CTEs resulting in good coefficient of thermal expansion (CTE) match with Ni-based superalloys from which the underlying structural components can be formed, the thermal conductivity and toughness of zirconia alloys can vary significantly depending on the alloying elements and compositions by which the ZrO2 is alloyed.

7YSZ has high toughness relative to other compositions of yttria stabilized zirconia as first recognized and shown in the furnace cyclic data of Stecura. (S. Stecura, “Optimization of the NiCrAl—Y/ZrO2-Y2O3 Thermal Barrier System,” NASA Technical Memorandum 86905, Cleveland, OH, 1985). Thereafter, the high toughness of 7YSZ was attributed as a result of YSZ's ferroelastic toughening mechanism. (C. Mercer, J. R. Williams, D. R. Clarke and A. G. Evans, “On a ferroelastic mechanism governing the toughness of metastable tetragonal-prime (t′) Yttria-stabilized zirconia,” Proceedings of the Royal Society A, vol. 463, no. 2081, 2007). Ferroelasticity increases the toughness of a material when that material is able to switch between equivalent crystallographic variants in the crystal structure upon mechanical loading. In the case of the tetragonal phase exhibited by 7YSZ, the tetragonal phase has three equivalent crystallographic variants between which the material can reversibly switch. These tetragonal variants correspond to the three possible orientations of the c-axis in the tetragonal crystal structure, where the c-axis and the two a-axes of the material are not equivalent (i.e., a=a≠c). Therefore, mechanical damage of 7YSZ thermal barrier materials can be mitigated by the reversible switching between such tetragonal variants leading to erosion resistant and FOD damage resistant materials. Conversely, the cubic phase of materials such as 20YSZ lack the presence of distinct crystallographic variants due to the three primary axes of the crystal being equivalent (i.e., a=a=a). The tetragonal crystal structure is required for the activation of this ferroelastic toughening mechanism in ZrO2-based materials and, absent such structure, no other viable toughening mechanism is present for ZrO2-based thermal barrier materials. Therefore, the tetragonal crystal structure is required for ferroelasticity induced erosion resistance in thermal barrier materials.

While ZrO2-based oxide materials are known to have relatively low thermal conductivity, it is desirable to reduce such property further for the effective operation of thermal barrier materials that are subject to increasingly higher operating temperatures. Efforts have been attempted to lower the ZrO2-based material thermal conductivity. One known method for further reducing a material system's thermal conductivity is through the introduction of mass disorder on the cation sub-lattice of a crystal structure that is known to have relatively low thermal conductivity already (M. R. Winter and D. R. Clarke, “Oxide Materials with Low Thermal Conductivity,” Journal of the America Ceramic Society, vol. 90, no. 2, pp. 533-540, 2007). This can be accomplished in ZrO2-based systems by increasing the stabilizer dopant concentration in the ZrO2 alloy and/or by increasing the number of types of stabilizer dopants in the alloy. For examples, 20 weight % yttria stabilized zirconia (20YSZ) and ZrO2 doped with three trivalent rare earth ions, Y3+, Eu3+, and Yb3+ (Tri-doped YSZ), both have lower thermal conductivity than 7YSZ. Therefore, it is possible to decrease the thermal conductivity of ZrO2 by using large amounts of multiple stabilizer dopants alloyed into the material, thereby increasing mass disorder on the cation sublattice. The disadvantage of this method of reducing thermal conductivity in thermal barrier materials is that both of these doping regimes, (i.e., the use of large amounts of stabilizer and the introduction multiple stabilizing ions of different sizes), tend to stabilize the cubic crystal structure of the ZrO2 system as opposed to the tetragonal phase present in 7YSZ. The cubic crystal structure is detrimental as it does not exhibit sufficiently high toughness as measured by erosion resistance and FOD resistance of the material. Consequently, this design approach creates a tradeoff of properties where the method for reducing thermal conductivity by increased doping concentrations also undesirably transforms the materials crystal structure to cubic which for the reasons explained hereinabove imparts a negative impact on the erosion resistance and FOD resistance of the material.

Accordingly, it is desirable to provide a TBC with both (i) lower thermal conductivity than 7YSZ, as well as (ii) high toughness of 7YSZ provided by the ferroelastic toughening mechanism. To accomplish both objectives, materials have been designed with multiple dopants providing sufficient mass disorder on the cation sub-lattice while also maintaining a material average cationic atomic size that favors tetragonal phase formation as opposed to cubic or other phases. One such multi-dopant material that has been shown to accomplish this combination of materials is the solid solution non-transformable tetragonal phase field (t) in the YO1.5—TaO2.5—ZrO2 system. (C. A. Macauley, A. N. Fernandez and C. G. Levi, “Phase equilibria in the ZrO2—YO1.5—TaO2.5 system at 1500 C,” Journal of the European Ceramic Society, vol. 37, no. 15, pp. 4888-4901, 2017; and C. A. Macauley, A. N. Fernandez, J. S. Van Sluytman and C. G. Levi, “Phase equilibria in the ZrO2—YO1.5—TaO2.5 system at 1250 C,” Journal of the European Ceramics Society, vol. 38, pp. 44523-4532, 2018).

This solid solution utilizes a combination of an oversized trivalent dopant combined with an undersized pentavalent dopant to maintain an average cationic atomic size that favors the formation of the tetragonal phase, while also allowing for total doping concentrations that can exceed 7 atomic % with a combination of multiple dopants and thereby substantially lower the thermal conductivity of the solid solution below that of 7YSZ. However, this solid solution phase is only stable over a relatively small compositional window that makes it difficult to manufacture both in powder and coating form by conventional material manufacturing processes used to manufacture TBC materials and coatings. A related material has been proposed in U.S. Pat. No. 11,479,846, where a similar composition to that above is manufactured. However, there are apparent deficiencies with the materials described in U.S. Pat. No. 11,479,846. Specifically, instead of achieving the single-phase low thermal conductivity, high toughness phase material, a combination of phases is produced. The use of a multi-phase material has significant drawbacks. For example, secondary phases can be produced that are not tetragonal and will not exhibit the ferroelastic toughening mechanism that provides erosion resistance. Additionally, the presence of one or more other types of phases are produced which do not have significant mass disorder on the cation lattice, which, in turn, translates to an insufficiently lowered thermal conductivity that provides thermal protection. Instead, the composite result of the materials performance will be a combination of the properties of the desirable phases and undesirable phases for each aspect of coating performance metrics.

As a result, there is an ongoing need for a thermal barrier material that does exhibit high toughness and low thermal conductivity.

### SUMMARY OF THE INVENTION

The invention may include any of the following aspects in various combinations and may also include any other aspect described below in the written description or in the attached drawings.

In a first aspect, a modified improved thermal barrier composition is provided, comprising a primary oxide comprising zirconium oxide and cerium oxide; a secondary oxide comprising one or more secondary oxide cations of the elements tantalum, niobium or a combination thereof; and a tertiary oxide selected from the group consisting of oxides of the rare earth elements, yttrium, scandium and any combination thereof.

In a second aspect, a modified thermal barrier material is provided, said material characterized as a substantially single phase of the non-transformable, solid solution tetragonal phase exhibiting phase stability for at least 100 hrs at elevated temperatures of at least 1500 deg C, a low thermal conductivity of less than about 2 W/m/K, a toughness equal to or greater than about 20 J/m² and a sintering resistance at a temperature of at least 1500° C. that incurs less microstructural degradation than a commercially available 7 weight percent yttria stabilized zirconia material.

In a third aspect, a modified improved thermal barrier composition is provided, comprising a primary oxide comprising zirconium oxide, hafnium oxide, or a combination therein and cerium oxide; a secondary oxide comprising one or more secondary oxide cations of the elements tantalum, niobium or a combination thereof; and a tertiary oxide selected from the group consisting of oxides of the rare earth elements, yttrium, scandium and any combination thereof.

### BRIEF DESCRIPTION OF THE DRAWINGS

The objectives and advantages of the invention will be better understood from the following detailed description of the preferred embodiments thereof in connection with the accompanying figures wherein like numbers denote same features throughout and wherein:

FIG. 1a shows a ternary phase diagram of a conventional Zr—Ta—Y oxide system with values shown in atomic percentages (at %), with each of the three axes in increments of 10 at %;

FIG. 1b shows a modified ternary phase diagram of FIG. 1a in accordance with the principles of the present invention with values shown in at %, with each of the three axes in increments of 10 at %; and

FIG. 2 shows an x-ray diffraction pattern for a powder material manufactured to have a composition in the expanded phase field of FIG. 1b showing a substantially single-phase, tetragonal material, in accordance with the principles of the present invention.

### DETAILED DESCRIPTION OF THE INVENTION

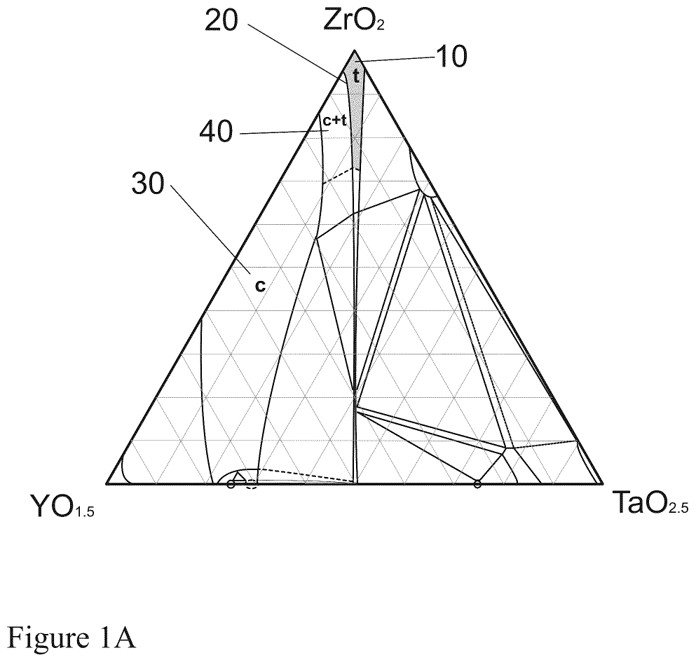

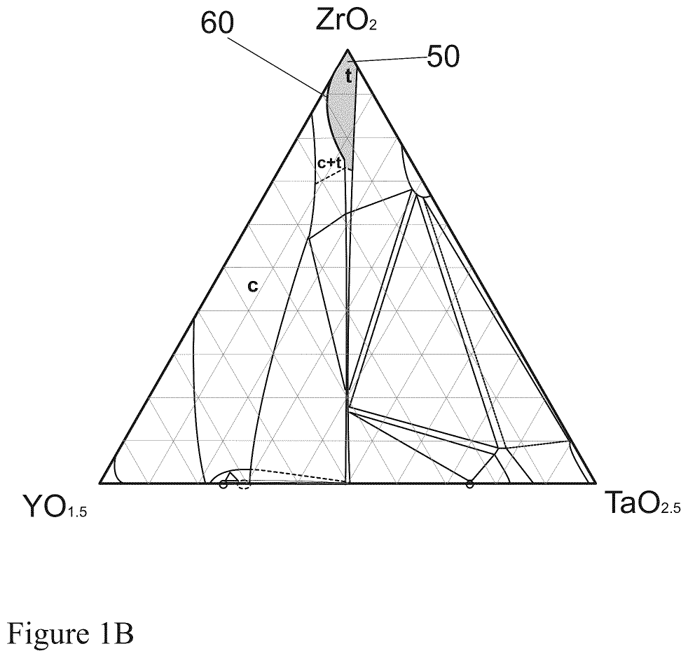

The emergence of the present invention overcomes the aforementioned deficiencies. The present invention pertains to compositions within a well-defined modified phase field 50 shown in FIG. 1b. The modified phase field 50 is a single phase, substantially non-transformable, solid solution, tetragonal phase. The compositions within such modified phase field 50 result in materials that exhibit low thermal conductivity while maintaining high toughness, thereby overcoming the tradeoff of such properties encountered by conventional materials.

The relationship and functioning of the various elements of this invention are better understood by the following detailed description. The detailed description contemplates the features, aspects and embodiments in various permutations and combinations, as being within the scope of the disclosure. The disclosure may therefore be specified as comprising, consisting or consisting essentially of, any of such combinations and permutations of these specific features, aspects, and embodiments, or a selected one or ones thereof.

The terminology includes the words specifically mentioned, derivatives thereof and words of similar import. The embodiments illustrated below are not intended to be exhaustive or to limit the invention to the precise form disclosed. The invention may include any of the following embodiments in various combinations and may also include any other aspect described below in the written description or in the attached drawings. These embodiments are chosen and described to best explain the principle of the invention and its application and practical use and to enable others skilled in the art to best utilize the invention.

Unless indicated otherwise, all percentages “%” as used herein are in units of atomic percentage designated as “at %” or “atomic %” or “atomic percent”.

As used herein and throughout, the term “conventional thermal barrier material” is intended to mean thermal barrier of the composition 7 weight % yttria stabilized zirconia (7YSZ).

As used herein and throughout, the term “material” is inclusive of the inventive composition that is manufacturable in any material format, such as powders and coatings.

As used herein and throughout, the term “phase stability” is intended to mean that the non-transformable, solid solution, tetragonal phase persists at elevated temperatures of at least 1500° C. for at least 100 hrs. As used herein and throughout, “solid solution” does not include a multi-phase material.

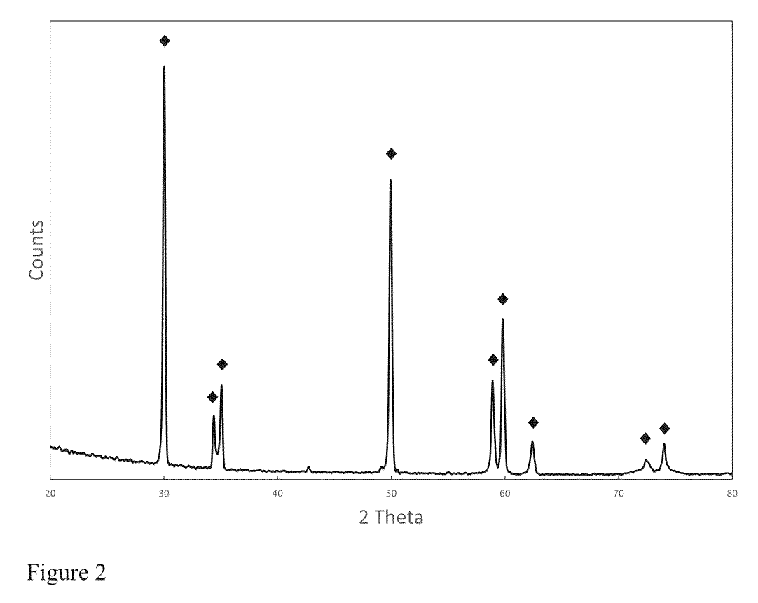

“Single phase” as used herein and throughout means a region of material that is structurally substantially uniform and distinctive, with a representation as shown in the XRD of the present invention at FIG. 2.

As used herein and throughout, the term “rare earth elements” is intended to mean herein and throughout elements lanthanum, cerium, praseodymium, neodymium, promethium, samarium, europium, gadolinium, terbium, dysprosium, holmium, erbium, thulium, and ytterbium and any combination thereof.

The inventors have recognized that for low thermal conductivity, high toughness thermal barrier coating (TBC) new generation materials to be effective, they preferably exhibit each of the following features: (1) the materials are phase stable in a substantially non-transformable tetragonal phase for over a hundred hours at a temperature of at least 1500° C.; (2) they are highly sintering resistant at a temperature of at least 1500° C. showing less microstructural degradation than a commercially available 7 weight percent yttria stabilized zirconia material; (3) they provide low thermal conductivity (i.e., “low k”) to the system of less than about 2 W/m/K; (4) they exhibit a toughness equal to or greater than existing commercial low-thermal conductivity thermal barrier materials of greater than about 20 J/m² and; (5) they are manufacturable (e.g., have a phase window that is broad enough to allow for fabrication of powders and coatings that maintain the desired non-transformable tetragonal phase throughout the manufacturing process). There is no thermal barrier system that currently has all of these features.

In addition to identifying the need for a single phase, non-transformable, solid solution tetragonal phase, the present invention has recognized the need to increase or expand the compositional range over which the non-transformable tetragonal phase field exhibits stability to thereby create effective TBCs with the hereinabove features. The conventional ZrO₂—YO_{1.5}—TaO_{2.5} system (reported in C. A. Macauley, A. N. Fernandez, J. S. Van Sluytman and C. G. Levi, “Phase equilibria in the ZrO2—YO1.5—TaO2.5 system at 1250C,” Journal of the European Ceramics Society, vol. 38, pp. 44523-4532, 2018) contains stability over a narrow compositional range of non-transformable tetragonal solid solution phase field with high tetragonality due to the combination of an oversized cation (Y3+) and an undersized cation (Ta5+) substituted onto the zirconia lattice in concert. Unfortunately, this material system poses significant processing and cost challenges. The inventors have determined that the drawbacks are due to the use of significant amounts of tantalum oxide and a small chemical processing window, which adversely impacts manufacturability, due to the stability over only a narrow compositional range of the non-transformable tetragonal phase field as shown in FIG. 1a. FIG. 1a illustrates the phase equilibria in the conventional ZrO₂—YO_{1.5}—TaO_{2.5} system at 1500 deg C. The non-transformable, solid solution tetragonal phase field is marked “t” which has been calculated and experimentally confirmed for the ZrO₂—YO_{1.5}—TaO_{2.5} system at 1500° C. This phase field 10 marked “t” as well as the phase field 30 marked “c” are both single phase fields on the phase diagram denoting the composition windows of the single phase tetragonal and cubic phase materials, respectively. The tetragonal phase field 10 shares a phase boundary 20 with an additional multi-phase field 40 marked “c+t.” This phase field 40 defines the compositional window over which materials will detrimentally exhibit both cubic and tetragonal phases.

The present invention offers a novel approach for producing thermal barrier materials with a non-transformable, tetragonal phase that exhibits stability over a sufficiently large compositional range. In particular, the present invention is directed to incorporating cerium oxide into the ZrO₂—YO_{1.5}—TaO_{2.5} ternary system as well as other functionally equivalent ternary systems described herein below. Cerium oxide is added into the ZrO₂—YO_{1.5}—TaO_{2.5} system to significantly increase the compositional range over which the non-transformable tetragonal phase field is created and remains stable, as clearly shown in phase field 50 in FIG. 1b. Ce cations can substitute onto the zirconium lattice and relax the oxygen crowding around the Zr⁴⁺ ions due to its larger ionic size compared to Zr⁴⁺, thereby maintaining the average cationic size required to produce the tetragonal phase. The overall manufacturability of the materials (e.g., powder composition and coatings) made therefrom will be significantly increased due to the increase in the compositional range within which the non-transformable, tetragonal phase field exhibits stability as shown by the comparison of the “t” phases (i.e., narrow phase field 10 in FIG. 1a versus enlarged phase field 50 in FIG. 1b). Specific increases in manufacturability that are possible by the present invention include a decreased sensitivity to the manufacturing process, and increased toughness due to the presence of a single phase, ferroelastically active material, and a decreased thermal conductivity due to the increase in mass disorder on the cationic sub-lattice. It should be understood that before emergence of the present invention, achieving lower thermal conductivity occurred at the expense of toughness, as both were considered competing design parameters.

Referring to FIG. 1b, the estimated position of the modified phase field boundary 60 for the new solid solution, non-transformable, tetragonal, single phase field 50, is calculated using a rule of mixtures calculation of average cationic size for the constituent elements of the modified material as defined by the symmetry and valence state of those elements as they will alloy into the ZrO2 tetragonal crystal structure. For the constituent elements alloyed into the tetragonal ZrO2 crystal structure, the cationic size of tetravalent cerium is 0.97 Angstroms, the cationic size of the tetravalent zirconium is 0.84 Angstroms, the cationic size of the trivalent dopant yttrium is 1.019 Angstroms, and the cationic size of the pentavalent dopant tantalum is 0.74 Angstroms. The compositions that define the modified phase field boundary 60 are calculated to have an average cationic size that is equivalent to the average cationic size of 18 atomic % ceria-stabilized zirconia. 18 atomic % ceria and the corresponding average cationic size of 0.8634 Angstroms represent the highest composition of cerium that can be added to the ZrO2 binary system that exhibits the solid solution tetragonal phase. Surpassing 18 atomic % ceria can cause the composition to not be single phase. The calculations are repeated with a selection of at % of Ce less than 18 at % to determine how much yttria and tantala must be present in the zirconia lattice to achieve the same or smaller average cationic size of 0.8634 Angstroms achieved with 18 at % cerium-stabilized zirconia. In this manner the modified phase boundary 60 is achieved, based on the average cationic size rule of mixtures for 18 at % CSZ.

Members of the ZrO₂—YO_{1.5}—TaO_{2.5} system, as represented by FIG. 1a, require intimate, vigorous mixing of cations on the lattice during processing to achieve significant phase stability. However, this typically requires energy intensive, chemical processing routes that can add significant cost and environmental hazards to the powder manufacturing. By adding a predetermined amount of cerium oxide into the solid solution of the ZrO₂—YO_{1.5}—TaO_{2.5} system and expanding the range of phase stability of its non-transformable tetragonal phase, the use of more practical solid solution processing techniques can produce resultant coating materials with significantly high temperature phase stability of the non-transformable tetragonal phase field. The incorporation of cerium oxide to expand the compositional range over which the non-transformable tetragonal phase field is stable produces a thermal barrier material that is not prone to phase decomposition on exposure to high temperatures for extended periods of time. In this manner, the materials of the present invention can offer manufacturability powder processing solutions that were not possible prior to the emergence of the present invention. In addition to expanding the range of acceptable powder processing techniques to include less energy intensive techniques, the use of cerium oxide as a co-dopant preferably reduces the amount of tantalum oxide needed to achieve stabilization of the non-transformable tetragonal phase field by changing the effective average ionic size of the cations on the lattice.

In another embodiment of the present invention, similar performance results will be observed for materials made for the same ternary system, for example, by using a pentavalent Nb oxide in place of or alongside Ta⁵⁺ oxide as the undersized dopant. Additionally, any of the trivalent rare earth oxides as well as yttrium and scandium oxide can be used as the oversized dopant ion either alone or in combination as these elements serve the same purpose in the stabilization of the non-transformable tetragonal phase field.

The composition of the present invention is selectively formulated to consist of a primary oxide, with the primary oxide comprising zirconium and/or hafnium oxide and cerium oxide; a secondary oxide comprising a secondary oxide cation of the elements tantalum and/or niobium; and a tertiary oxide selected from the group consisting of the rare earth elements, yttrium and scandium or any combination thereof. Trace impurities of about 0.5 atomic percent or less may be contained in the composition. Primary oxide as used herein and throughout is intended to mean that it is present in the largest quantity. It should be understood that the secondary oxides and tertiary oxides can be utilized in any amount so long as each is contained in an amount less than the primary oxides.

Without being bound by any theory, the inventors believe that the addition of cerium to the YO1.5—TaO2.5—ZrO2 system increases the size of the single phase, tetragonal solid solution phase by entering the system as a tetravalent dopant with an ionic size of approximately 0.97 Angstroms, which is greater than that of tetravalent zirconium in the zirconium oxide crystal lattice (0.84 Angstroms), but smaller than the trivalent dopant yttrium (1.019 Angstroms) and larger than the pentavalent dopant, tantalum (0.74 Angstroms). This mid-size cerium dopant acts to stabilize the tetragonal phase without the introduction of oxygen vacancies and thereby results in a more stable tetragonal structure. Additionally, trivalent dopant ytterbium with a cationic size of 0.985 Angstroms can be substituted for yttrium in greater quantities while maintaining an average cationic size below the upper limit of 0.8634 Angstroms, thereby desirably increasing the size of the modified solid solution, non-transformable, tetragonal phase field for the ternary system YbO1.5—TaO2.5—ZrO2.

Exemplary examples of compositions bounded by the preferred modified phase field are now described. The composition of the oxide is between about 2 and about 20 atomic percent cerium oxide, about 1 and about 15 atomic percent tantalum oxide, and between about 1 and about 15 atomic percent ytterbium oxide with the balance ZrO2. More preferably, an exemplary compositional window occurs where the cerium oxide is between about 5 and about 15 atomic percent tantalum oxide, is between about 1 and about 7 atomic percent, and ytterbium oxide is between about 5 and about 10 atomic percent with the remainder being zirconium oxide. All chemistries having the aforementioned ranges are within the modified phase field 50 of FIG. 1b and are therefore advantageously single phase, non-transformable, tetragonal, solid solution phase.

### Illustrative Example

A powder having a composition within the modified phase field 50 (“t”) of FIG. 1b was prepared by typical solid solution processing techniques. An x-ray diffraction pattern of the powder material was obtained. The x-ray diffraction pattern is shown in FIG. 2 and is indicative of a solid solution, tetragonal single-phase material consistent with the present invention. The positions of the diamonds in FIG. 2 indicate the locations where the peaks of a solid solution, tetragonal, single-phase material are expected to occur. The alignment of the diffraction pattern peaks with the positions of the diamonds confirms the presence of a solid solution, tetragonal, single-phase material. The peaks for other phases were not observed in FIG. 2. This test validated the manufacturability of the materials of the present invention. In contrast, the most relevant compositions without cerium prior to the present invention have been observed to be multiple phase as denoted by multi-phase field 40 in FIG. 1a and reported in the published literature. (C. A. Macauley, A. N. Fernandez, J. S. Van Sluytman and C. G. Levi, “Phase equilibria in the ZrO2—YO1.5—TaO2.5 system at 1250C,” Journal of the European Ceramics Society, vol. 38, pp. 44523-4532, 2018).

The modified TBC compositions of the present invention can be utilized as part of any suitable TBC system, including, by way of example, as part of a yttria stabilized zirconia (YSZ) layer that is situated between a bond coat and the modified TBC compositions of the present invention to exhibit a non-transformable, tetragonal phase. The layers of the TBC system may include (i) the inventive low thermally-conductive barrier coating (which may be formed on top of a bond coat) with a composition forming a non-transformable, tetragonal phase offering more thermal protection at higher operating temperatures (e.g. 1350 C or higher; (ii) a commercially available YSZ TBC acting as an additional layer to enhance bonding by decreasing the coefficient of thermal expansion (CTE) mismatch stress between layers; (iii) continuous oxide layer (TGO) formed on top of the metallic bond coat; (iv) a metallic bond coat with additional chromium and/or aluminum to improve oxidation protection; and (v) a high temperature material acting as the substrate for the critical component. Other suitable examples are also contemplated. Generally speaking, incorporation of the TBCs of the present invention with other layers to form an improved thermal barrier system can provide a so-called “tough phase” with lower thermal conductivity. The TBC materials of the present invention can be applied with a microstructure offering increased strain tolerance (providing a longer life after repeated thermal cycling) resulting in a TBC system with substantially improved performance that allows increased thermal protections while meeting the design criteria (life after repeated thermal cycling). The present invention can enhance a thermal barrier system and allow components operating in a high temperature environment to perform at higher surface temperatures and exhibit a longer life. The TBC materials of the present invention can be disposed in a layer on an airfoil or a turbine component in a thickness that can range from about 1 to about 1500 microns, or more preferably, from about 25 to about 1000 microns. The TBC material can be deposited by any suitable technique known in the art, including atmospheric plasma spray or electron beam vapor deposition. The TBC material preferably has a columnar structure when deposited by electron beam vapor deposition.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A modified improved thermal barrier composition, comprising
a primary oxide comprising zirconium oxide and cerium oxide;
a secondary oxide comprising one or more secondary oxide cations of the elements tantalum, niobium or a combination thereof; and
a tertiary oxide selected from the group consisting of oxides of the rare earth elements, yttrium, scandium and any combination thereof.

2. The modified thermal barrier composition of claim 1, wherein the composition produces a substantially single phase, non-transformable, solid solution tetragonal solid solution phase material.

3. The modified thermal barrier composition of claim 1, wherein the secondary oxide cation is tantalum.

4. The modified thermal barrier composition of claim 1, wherein the secondary oxide cation is niobium.

5. The modified thermal barrier composition of claim 1, wherein the tertiary oxide is an oxide of yttrium.

6. The modified thermal barrier composition of claim 1, wherein the tertiary oxide is an oxide of ytterbium.

7. The modified thermal barrier composition of claim 1, wherein the composition comprises, based on total atomic percent the following:
about 2 to about 20 atomic percent CeO2;
about 1 to about 15 atomic percent secondary oxide;
about 1 to about 15 atomic percent tertiary oxide;
about 0.5 atomic percent or less of trace impurities; and
a balance of ZrO2 therein.

8. The modified thermal barrier composition of claim 1, wherein the composition comprises, based on total atomic percent:
about 5 to about 15 atomic percent CeO2;
about 1 to about 7 atomic percent of the secondary oxide;
about 5 to about 10 atomic percent of the tertiary oxide;
about 0.5 atomic percent or less of trace impurities; and
a balance of ZrO2 therein.

9. The modified thermal barrier composition of claim 1 wherein the primary oxide is substantially zirconium oxide, the secondary oxide is substantially tantalum oxide, and the tertiary oxide is substantially ytterbium oxide.

10. The modified thermal barrier composition of claim 1, wherein the secondary oxide is tantalum oxide and the tertiary oxide is ytterbium oxide.

11. The modified thermal barrier composition of claim 1, wherein the composition produces a substantially single phase, tetragonal solid solution phase material.

12. A modified thermal barrier material, said material characterized as a substantially single phase of the non-transformable, tetragonal phase exhibiting phase stability for at least 100 hrs at elevated temperatures of at least 1500 deg C, a low thermal conductivity of less than about 2 W/m/K, a toughness equal to or greater than about 20 J/m² and a sintering resistance at a temperature of at least 1500 deg C, that incurs less microstructural degradation than a commercially available 7 weight percent yttria stabilized zirconia material.

13. The modified thermal barrier material of claim 12 disposed in a layer on an airfoil, wherein a thickness of the layer is from about 1 to about 1500 microns.

14. The modified thermal barrier material of claim 12 disposed in a layer on a turbine component, wherein a thickness of the layer is from about 25 to about 1000 microns, and wherein the thermal barrier coating is deposited by atmospheric plasma spray.

15. The modified thermal barrier material of claim 12 disposed in a layer on a turbine component, where a microstructure of the layer is columnar, and wherein the layer is deposited by electron beam-physical vapor deposition.

16. The thermal barrier coating composition of claim 1, wherein a bond coat is provided over a substrate comprising a turbine engine component.

17. A modified improved thermal barrier composition, comprising
a primary oxide comprising zirconium oxide, hafnium oxide, or a combination therein and cerium oxide;
a secondary oxide comprising one or more secondary oxide cations of the elements tantalum, niobium or a combination thereof; and
a tertiary oxide selected from the group consisting of oxides of the rare earth elements, yttrium, scandium and any combination thereof.
